(19) United States
(12) Patent Application Publication
(10) Pub. No.: US 2010/0248197 A1
(43) Pub. Date: Sep. 30, 2010

(54) DEVICE AND METHOD FOR ACTING ON A PERSON'S MOTOR AUTOMATISM

(75) Inventor: Bernard Gasquet, Aix en Provence (FR)

Correspondence Address: DENNISON, SCHULTZ & MACDONALD, 1727 KING STREET, SUITE 105, ALEXANDRIA, VA, 22314, US

(73) Assignee: ACTIVA CONCEPTS, St. Jean de Muzols (FR)

(21) Appl. No.: 12/294,949

(22) PCT Filed: Apr. 5, 2007
(86) PCT No.: PCT/FR2007/051078

§ 371 Date: Dec. 3, 2008

(30) Foreign Application Priority Data
Apr. 6, 2006 (FR) 0651233

(51) Int. Cl. G09B 19/00; H03K 3/00

(52) U.S. Cl. 434/236; 327/291

(57) ABSTRACT

The invention relates to a sound device for acting on the motor automatisms of a person including:
means for generating pulsed sounds SPᵢ each having a frequency comprised between 200 and 1,500 Hz and a duration comprised between 2 and 20 s, each of the pulsed sounds being separated by a time interval ΔT comprised between 2 and 60 s,
means for controlling the emission and stopping of the pulsed sounds,
means for generating associated sounds SA each having a frequency comprised between 2 and 200 Hz and a duration comprised between 2 and 60 s,
means for triggering the emission of an associated sound,
and control means adapted in order to interrupt the emission of pulsed sounds SPᵢ and to provide the emission of at least one associated sound SA upon receiving an order for triggering an associated sound.

The present invention relates to the technical field of acoustics for acting on the operation of the brain, and it is more specifically directed to a device for acting on the motor automatisms of a person.

In order to execute movements in view to reaching a determined goal, each individual unconsciously creates motor automatisms for relieving the conscious voluntary mind.

Indeed, for performing a race or a throw for example, the number and the complexity of the applied mechanisms rapidly lead to exceeding the voluntary control capabilities of the brain.

It is found that some of the programmed automatisms do not allow proper execution of the movement or that the programming of certain automatisms is disabled. Acquisition, correction and/or re-enabling of automatic programs may prove to be very problematic, very long, or even impossible.

With the state of knowledge in neurosciences, it is possible to know that:
the conscious voluntary mind (from the cortical areas of the brain) is unable to control or therefore instantaneously modify, during an action, the activity of the (sub-cortical) brain areas responsible for enabling the motor automatic programs. This means that it is impossible by sole intention, to change a [symbol] bad [symbol] gesture into a <<good>> gesture instantaneously,
acquiring or re-acquiring an automatic gesture is therefore only possible by intentional repetitions of this gesture, as intended by the cortex, and which the subcortex should end up by programming and restoring them. The number of these repetitions may be very high. It determines the acquisition time. This acquisition time depends on the nature of the gesture, on the intrinsic capacity of the individual (his/her motor control qualities, the power of his/her body scheme, etc.), on the punctual intentionality conditions, on a certain number of other factors and on relationships between all these factors. This what explains the uncertainty on the acquisition time, which is the fate of all the training sessions for acquiring or modifying technical ability,
the voluntary conscious mind may imagine a gesture and its sensorial (kinesthetic) contents, without carrying it out. It has been shown by many laboratories of neurosciences applied to movement, and by medical imaging, that brain activity activated for proprioceptive imagination of the gesture was in part identical with that created for actually carrying out this same gesture. The brain partly (centre and nature of the activity) operates in the same way for carrying out a gesture or imagining proprioceptive perception of this gesture,
the subcortical areas activated in programming and controlling the execution of automatic gestures with priority comprise the thalamus and a portion of the limbic system notably.

The object of the invention is therefore aimed at solving the problem of having the conscious mind access the programming of the motor automatisms, in order to suppress the need for learning repetitions, and therefore to considerably reduce both time, hazard and drawbacks.

The invention proposes a neurophysiological device providing voluntary action, within a highly reduced time, on subcortical (thalamic and limbic) brain areas responsible for programming and activating the programs of motor automatisms, other than by repetition preceded with intention.

The device uses both the knowledge of a certain operating mode of the brain, and certain characteristics of certain low frequency sounds for:
creating in the subject conditions required for the desired motor (re)programming, by placing him/her in a condition of under-awakedness, and out of action, a favorable condition for the intended brain activity in order to activate particular neuronal routes for accessing subcortical areas,
activating these neuronal routes so that the contents of desired automatic motor programs may be identified and recorded by the relevant subcortical areas.

The brain operating mode implements:
results of experiments on the capabilities of low frequency sounds and on their effects on memorization mechanisms,
the role of subcortical centers (thalamus, limbic system) in memorizing sensorial messages,
the role and the characteristics of different transmission routes for sensorial messages,
the modes for recording sensorial messages by the subcortical centers.

Generating low frequency sounds is provided by a programmed sound generator which broadcasts to the subject two types of sound signals corresponding to the two goals above:
an automatic sequence of sounds, continuously broadcasted and without any intervention from the subject for creating the condition of under-awakedness,
a sound, clearly different from the sounds of the sequence, and the emission of which is controlled at will by the subject, for memorization.

The global method of (re)programming requires that the sound session be preceded by a technical session, the purpose of which is:
to have the subject identify the gesture which should be the object of (re)programming. Identification is achieved in a first phase in technical terms, in a second phase in biomechanical terms, and in a third phase in proprioceptive (kinesthetic) terms corresponding to the personalized inner life experience,
to train the subject to mentally recreate these inner proprioceptive contents of the gesture without producing any actual gesture.

With the sound session, it is possible to achieve both of the aforementioned goals:
preliminary goal: place the subject in a condition of relaxation and receptivity, by having him/her hear the continuous sequence of pulsed sounds. Once he/she is in this condition, he/she is capable of mentally recreating the proprioceptive characteristics of the gesture, out of action, and without producing any actual gesture, further, by hearing the continuous sequence of low frequency pulsed sounds, it is possible to access the reticular route which should be used for achieving the main goal,
main goal: have the actual subject associate the proprioceptive message (corresponding to the desired gesture) with a specific sound emitted on demand by the generator, when his/her mental production of the proprioceptive contents seems to be sufficiently compliant with the desired gesture.

The method uses an operating mode of the brain in an organized and controlled way. The brain perceives sensorial messages in two simultaneous ways, through two different routes: a unisensorial route, and a plurisensorial route.
the unisensorial route is that of the main sense in which the message is identified (hearing, sight, smell, touch, taste). This route is very selective for efficiency purposes. The brain always selects it with priority. Consciousness is also focused on this route. For the same reasons of efficiency, it follows a direct path between the sensorial organ and the cortex, via the thalamus (the route is said to be <<thalamocortical>>),
when a message is perceived through this unisensorial route, all the other senses continue to operate, but out of the field of conscious perception. This second route is said to be plurisensorial. It is the reticular route. It is more complex, longer and richer. It does not directly participate in the action, but it notably contributes to memorizing the elements of the action. It follows a path which applies the limbic system. It is said to be <<thalamolimbocortical>>. The brain does not consciously follow this route. In order to activate and access it in order to let through voluntary conscious messages, the person should extract himself/herself out of the unisensorial <<action>> mode, while remaining conscious and awaked.

Low frequency sounds have the capability of placing brain activity in the under-awakedness mode (out of action). They open the reticular route. When this route is open, the mind may use it for sending and perceiving several sensorial messages.
two distinct sensorial messages are sufficient for significantly characterizing an activity for the memorization (thalamolimbic) system. This avoids having to handle too complex messages applying three or four senses. It is then sufficient to send to the relevant subcortical areas two sensorial messages which transit through the reticular route: a proprioceptive message, and a sound message for example,
knowledge in acoustics and long neurophysiological research work have allowed sound frequencies to be defined which are the best perceived and the best identifiable by the subcortical centers responsible for selecting the messages to be memorized. Moreover, these frequencies should be clearly perceptible by the mind (therefore audible), be easily reproducible (sounds have to be repeated in a strictly identical way) and further they should not have perturbing secondary effects,
the other characteristics of these sounds have been determined in order to make the messages more selective, significant and easy to perceive (durations, successions, intensities).

The method therefore consists of sending through the reticular route to the relevant subcortical areas a complex sensorial message which will be perceived as significant and [symbol] recordable [symbol] since it consists of two components:
a proprioceptive sensorial component (the contents of the motor program corresponding to the desired technical gesture),
a sound sensorial component (the associated low frequency sound), this plurisensorial message simultaneously reaches the same subcortical areas (thalamus and limbic system).

By means of the followed plurisensorial route, and of the conscious association of both messages on this route, the prioprioceptive message is received and recorded as programmed and may be restored in the case of any future voluntary command.

This new route activated by the method is the one which the motor program will follow in the future when the voluntary command will call for an automatic response.

The second (sound) signal is only required for activating the route at the stage for recording the program. It is no longer necessary subsequently:
the <<new program>> does no longer need any stimulus for appearing, since it has been recorded as a systematic response. The command alone is sufficient for triggering, like any other automatism acquired by the customary repetition routes.

When an automatic gesture learned traditionally is carried out, the learning operations of this gesture are not repeated, but initiation of the gesture is triggered by voluntary intention. This is also the case when the question is of carrying out an automatic gesture acquired by the method:
the method is applied for recording an automatism, which itself will create the actual gesture from the voluntary intention.

The object of the invention is therefore directed to a sound device for acting on the motor automatisms of a person including:
means for generating pulsed sounds each having a frequency comprised between 200 and 1,500 Hz and a duration T comprised between 2 and 20 s, each of these pulsed sounds being separated by a time interval comprised between 2 and 60 s,
means for controlling the emission and stopping the pulsed sounds,
means for generating associated sounds each having a frequency comprised between 2 and 200 Hz and a duration comprised between 2 and 60 s,
means for triggering the emission of an associated sound,
and control means connected to means for generating pulsed sounds, to means for generating an associated sound, and to means for triggering an associated sound, and adapted in order to interrupt the emission of pulsed sounds and to provide the emission of at least one associated sound upon receiving an order to trigger an associated sound.

According to a preferred embodiment characteristic, the means for generating pulsed sounds provide the emission of pulsed sounds having a frequency preferably comprised between 200 and 400 Hz and a duration comprised between 5 and 9 s, and preferably equal to 7 s.

According to another advantageous characteristic of the invention, the means for generating pulsed sounds provide the emission of pulsed sounds each separated by a time interval preferably comprised between 10 and 15 s.

According to an alternative embodiment, the means for generating pulsed sounds successively emit pulsed sounds with different frequencies.

According to another characteristic of the object of the invention, the means for generating associated sounds provide the emission of associated sounds each having a frequency preferably comprised between 50 and 150 Hz.

According to another characteristic of the object of the invention, the means for generating associated sounds provide the emission of associated sounds each having a duration preferably comprised between 5 and 15 s.

Advantageously, the means for generating the associated sounds include means for adjusting the frequency and/or the duration and/or the intensity of the associated sounds.

It should be noted that the means for triggering the emission of an associated sound is of the manual or automatic triggering type.

Another object of the invention is to propose a method for acting on the programming or reprogramming of the automatisms of a user including for at least one work session, the following steps:
emitting a series of pulsed sounds each having a frequency comprised between 200 and 1,500 Hz and a duration comprised between 2 and 20 s, while being separated from each other by a time interval comprised between 2 and 60 s,
interrupting the emission of pulsed sounds, in order to provide the emission of at least one associated sound having a frequency comprised between 2 and 200 Hz and a duration comprised between 2 and 60 s,
and emitting pulsed sounds after stopping the emission of the associated sound.

According to a characteristic of the object of the invention, the method consists of interrupting the emission of pulsed sounds and of emitting an associated sound, upon occurrence of an order from the user or upon automatic triggering.

Advantageously, the method consists of providing the emission of the associated sounds, for a number of occurrences of the associated sounds, comprised between 2 and 10 and preferably equal to 6.

According to a preferred embodiment characteristic, the method consists of emitting pulsed sounds, having a frequency comprised between 200 and 400 Hz and a duration comprised between 5 and 9 s, each being separated by a time interval comprised between 10 and 15 s.

Advantageously, the method consists of successively emitting pulsed sounds having different frequencies.

Preferably, the method consists of emitting associated sounds each preferably having a frequency comprised between 50 and 150 Hz with a duration comprised between 5 and 15 s.

According to an alternative embodiment, the method consists of selecting the duration and/or the frequency and/or the intensity of the associated sounds.

Various other characteristics become apparent from the description made below with reference to the appended drawings which show, as non-limiting examples, embodiments of the object of the invention.

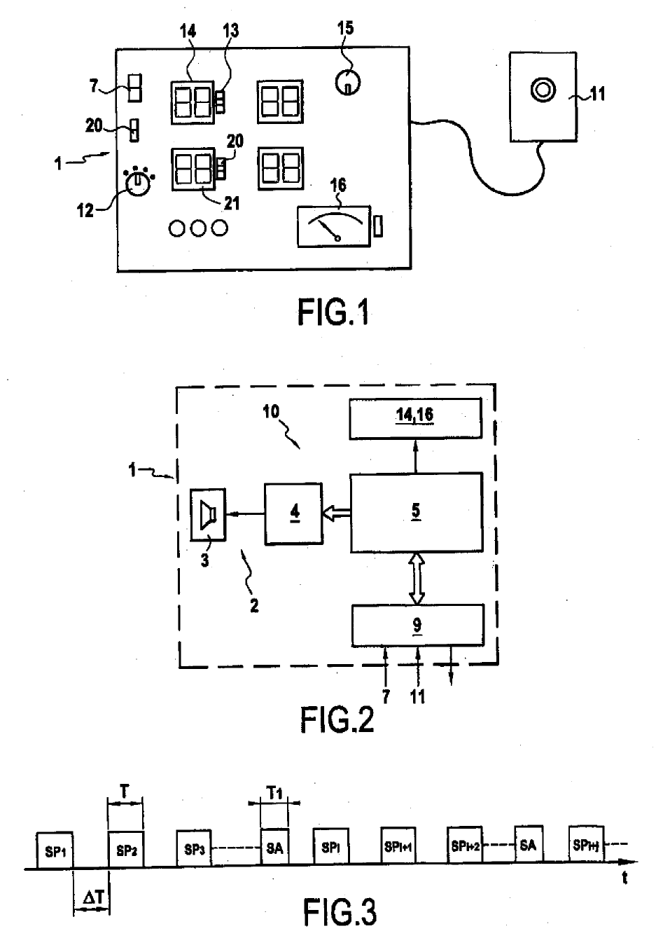

FIG. 1 is a view of an exemplary embodiment of the front face of a sound device according to the invention.

FIG. 2 is a functional diagram of an exemplary embodiment of a sound device according to the invention.

FIG. 3 is an exemplary time diagram illustrating certain characteristics of a sound device according to the invention.

As this is more specifically seen in FIGS. 1 and 2, the object of the invention relates to a device or a sound apparatus 1 suitable for acting on the motor automatisms of a person.

This device 1 includes means 2 for generating a first series of so-called pulsed sounds SPᵢ. As this is more specifically seen in FIG. 3, the generation means 2 are capable of delivering a series of pulsed sounds SP1, SP2, SP3, . . . SPi, . . . each having a frequency comprised between 200 and 1,500 Hz and preferably comprised between 200 and 400 Hz. Each pulsed sound SR has a duration T comprised between 2 and 20 s and advantageously comprised between 5 and 9 seconds and preferably equal to 7 seconds. Two consecutive pulsed sounds SPᵢ are separated by a silent period, the duration ΔT of which is comprised between 2 and 60 seconds and advantageously comprised between 10 and 15 seconds.

The means for generating pulsed sounds 2 are produced in any suitable way. For example, the generation means 2 include a loudspeaker or preferably a headphone 3 driven by a control circuit 4 connected to a processing and control unit 5 architectured around at least one microprocessor.

The sound device 1 also includes means 7 for controlling the emission and the stopping of the pulsed sounds SPᵢ. For example, these control means 7 may be made with a switch for starting the apparatus which in the operating position allows pulsed sounds SP; to be delivered. These control means 7 are connected through an input/output interface circuit 9 connected to the processing and control unit 5.

The sound device 1 also includes means 10 for generating so-called associated sounds SA each having a frequency comprised between 2 and 200 Hz and preferably a frequency comprised between 50 and 150 Hz. Each associated sound SA has a duration T1 comprised between 2 and 60 seconds and preferably a duration comprised between 5 and 15 seconds. The means 10 for generating associated sounds are preferably produced via the loudspeaker or the headphone 3 driven by the control circuit 4.

The sound device 1 includes means 11 for triggering the emission of an associated sound SA. Preferably, the means 11 are of the manual triggering type and are for example formed via a push button connected to the processing and control unit 5, via the interface circuit 9. Of course, the means 11 for triggering the emission of an associated sound may be of an automatic nature as this will be explained in the description which, follows.

The sound device 1 also includes suitable control means for interrupting the emission of pulsed sounds SPᵢ and for providing the emission of at least one associated sound SA upon receiving an order to trigger an associated sound. It should be understood that when an order to trigger an associated sound is delivered by the triggering means 11, the emission of pulsed sounds SP; is interrupted and at least one associated sound SA is emitted. After emission of an associated sound SA, the emission of pulsed sounds SP; is resumed. These control means are advantageously achieved by the processing control unit 5.

The sound device 1 according to the invention enables a user to apply a process or a method for acting on some of his/her motor automatisms. The sound device 1 is thus used by a person during a work session in order to modify, program or activate a motor automatism corresponding to the execution of a gesture or a movement.

During a work session, the sound device 1 is started by the control means 7 in order to allow emission of pulsed sounds SPᵢ. The sound device 1 thus emits a series or train of pulsed sounds SPᵢ each having a duration T and separated from each other by silent periods of duration ΔT. These low frequency pulsed sounds SPᵢ which are separated by silent intervals of duration ΔT, allow the person who is listening to them to be placed in an under-awakedness condition.

When the person is in this under-awakedness condition, this person then mentally creates an image of the desired gesture or movement accompanied by associated kinesthetic sensations. When the person has mentally created the mental image of the gesture or of the movement and the associated sensations, the person records them by providing the emission of an associated sound SA. The control of the triggering means 11 by the person leads to the stopping of the emission of pulsed sounds SP; and to the emission of an associated sound SA.

After stopping the associated sound SA emission, the pulsed sounds SPᵢ are again emitted automatically. Advantageously, the person repeats the operation several times, consisting of mentally creating a mental image accompanied by associated sensations. Every time, the emission of pulsed sounds SPᵢ is stopped so that an associated sound SA is emitted at each command from the triggering means 11. It should therefore be understood that the pulsed sounds SPᵢ are interrupted several times in order to allow emission of the associated sounds SA. The occurrences of the associated sounds SA exclusively depends on the intention of the person who selects the moments when the mental image is created. Thus, the time between the emission of the associated sounds SA may assume very different or substantially identical values of the order of a few seconds or several minutes.

Advantageously, the work session is finished upon completion of a determined number of emissions of associated sounds SA, comprised between 2 and 10 and preferably equal to 6. In other words, it is considered that after repeated marking of the gesture preferably equal to 6, the corresponding motor automatism was able to be modified, programmed or activated. The person may then act on the means 7 for controlling the stopping of the pulsed sounds.

It emerges from the object of the invention that the sound device 1 thus emits pulsed sounds SPᵢ interrupted several times by an associated sound SA. According to a preferred alternative embodiment, the pulsed sounds SPᵢ are successively emitted one after the other with different frequencies. In other words, during a work session, the emitted pulsed sounds SPᵢ have different frequencies.

It should be noted that during a work session, the pulsed sounds SA are emitted according to a same frequency. However, it is to be noted that the sound device 1 includes means 12 for adjusting or selecting the frequency of the associated sounds SA as well as means 13 for adjusting or selecting the duration of the associated sounds SA. Preferably, the sound device 1 also includes a display 14 for the duration selected for the associated sounds SA.

The sound device 1 also includes means 15 for adjusting the intensity of the emitted sounds (SPᵢ and SA) as well as a display 16 of the sound volume. The sound device 1 also includes means 20 for selecting the operating mode of the sound device, either in a manual mode as described above, or in an automatic mode.

Indeed, according to another preferred characteristic of the invention, the sound device 1 includes an automatic operating mode for which the emission of the associated sounds SA is not triggered by the person but by the sound device 1 which produces the order for triggering an associated sound SA. The characteristics (frequency, duration, intensity) of the pulsed sounds SP_{I} and of the associated sounds SA are identical with those of the manual mode. In the automatic mode, the associated sounds SA are separated by silent periods, the duration of which is comprised between 2 and 60 seconds. The sound device 1 advantageously includes means 20 for adjusting these silent periods in the automatic mode and means 21 for displaying the duration of these silent periods in the automatic mode.

The sound device 1 appears as an apparatus which is simple to apply. Of course, this sound device 1 may be produced with different technical means of the software and/or hardware type, appearing as a standalone apparatus or a microcomputer.

The method according to the invention may be used by applying the following procedure broken down into four phases:

1. Analysis of the movement:
a) Picture-taking of the subject in action.
b) Technical analysis by the coach.
c) Biomechanical analysis.
d) Proprioceptive analysis.

2. Identification by the subject of prioprioceptive sensations corresponding to the analyzed gesture, by repetitions in slow motion, until he/she is capable of memorizing them and of recreating them mentally (without actual producing them).

3. Session for neurophysiological modification of the gesture with the use of the Pulsed Sound Generator:
a) The subject is placed out of action, and placed in a relaxation condition by listening to the pulsed sounds (SP).
b) Modification of the gesture is achieved by juxtaposition of the Associated Sound (SA), controlled by the subject and of the mental creation (without actual production) of the proprioceptive sensations analyzed and identified in phases 1 and 2.

4. Picture-taking of the subject in action under the same conditions as in phase 1 and video analysis of the acquired modified gesture.

This procedure may be applied for modifying any identified and codified automatic technical sports gesture.

It has notably been successfully applied in the following sports: tennis (serving, forehand, backhand stroke), golf (various portions of the swing and of the backswing, overswing, change of support, angulation and bracing of the wrists, pivoting the pelvis, etc.) athletics (time for responding to the start signal, change in the centre of gravity upon running, rotation in throws), football or rugby (amplitude, kick accuracy on the strong foot and the weak foot), volleyball (service, interfering foot movements), basketball (body movements for aiming at the basket, improving accuracy), Basque pelota (development of the shooting amplitudes on the weak side), fencing (fixing the wrist), shooting (pivoting the chest), etc.

With this general procedure, the method according to the invention may be applied to restoring or acquiring motor automatisms damaged as a result of accidents of various origins, having affected the central nervous system, while having spared the peripheral motor organs.

It was tested positively on cases of hemiplegia (congenital hemiplegia or sequels of a cerebrovascular stroke) and of associated spasticity, of tetraparesis subsequent to prolonged traumatic coma, of disability of the secondary locomotor apparatus, and of psychomotor inhibition as a result of an injury and a surgical operation.

1. A sound device for acting on motor automatisms of a person, characterized in that it includes:
means (2) for generating pulsed sounds (SPᵢ) each having a frequency comprised between 200 and 1,500 Hz and a duration T comprised between 2 and 20 s, each of these pulsed sounds being separated by a time interval (DT) comprised between 2 and 60 s,
means for controlling the emission and stopping of the pulsed sounds,
means (10) for generating associated sounds (SA) each having a frequency comprised between 2 and 200 Hz and a duration (T₁) comprised between 2 and 60 s,
means (11) for triggering the emission of an associated sound,
and control means connected to the means (2) for generating pulsed sounds, to the means (10) for generating an associated sound and to the means (11) for triggering an associated sound, and adapted in order to interrupt the emission of pulsed sounds and provide the emission of at least one associated sound upon receiving an order for triggering an associated sound.

2. The device according to claim 1, characterized in that the means (2) for generating pulsed sounds provide the emission of pulsed sounds having a frequency preferably comprised between 200 and 400 Hz and a duration (T) comprised between 5 and 9 s, and preferably equal to 7 s.

3. The device according to claim 1, characterized in that the means (2) for generating pulsed sounds provide the emission of pulsed sounds each separated by an time interval (DT) preferably comprised between 10 and 15 s.

4. The device according to claim 1, characterized in that the means (2) for generating pulsed sounds successively emit pulsed sounds with different frequencies.

5. The device according to claim 1, characterized in that the means (10) for generating associated sounds provide the emission of associated sounds (SA) each having a frequency preferably comprised between 50 and 150 Hz.

6. The device according to claim 5, characterized in that the means (10) for generating associated sounds (SA) provide the emission of associated sounds each having a duration (T₁) preferably comprised between 5 and 15 s.

7. The device according to claim 5, characterized in that the means (10) for generating the associated sounds (SA) include means for adjusting the frequency and/or the duration and/or the intensity of the associated sounds.

8. The device according to claim 1, characterized in that the means (11) for triggering the emission of an associated sound is of the manual or automatic triggering type.

9. A method for acting on the programming or re-programming of motor automatisms of a user, characterized in that it includes, for at least one work session, the following steps:
emitting a series of pulsed sounds (SPᵢ) each having a frequency comprised between 200 and 1,500 Hz and a duration (T) comprised between 2 and 20 s, while being separated from each other by a time interval (DT) comprised between 2 and 60 s,
interrupting the emission of the pulsed sounds, in order to provide the emission of at least one associated sound (SA) having a frequency comprised between 2 and 200 Hz and a duration (T₁) comprised between 2 and 60 s,
and emitting pulsed sounds (SPᵢ) after stopping the emission of the associated sound (SA).

10. The method according to claim 9, characterized in that it consists of interrupting the emission of the pulsed sounds (SPᵢ) and of emitting an associated sound (SA), upon occurrence of an order from the user or upon automatic triggering.

11. The method according to claim 9, characterized in that it consists of providing the emission of the associated sounds (SA), for a number of occurrences of the associated sounds (SA) comprised between 2 and 10 and preferably equal to 6.

12. The method according to claim 9, characterized in that it consists of emitting pulsed sounds (SPᵢ) having a frequency comprised between 200 and 400 Hz and a duration (T) comprised between 5 and 9 s, while being separated from each other by a time interval (DT) comprised between 10 and 15 s.

13. The method according to claim 12, characterized in that it consists of successively emitting pulsed sounds (SPᵢ) having different frequencies.

14. The method according to claim 9, characterized in that it consists of emitting associated sounds (SA), each preferably having a frequency comprised between 50 and 150 Hz with a duration (T₁) comprised between 5 and 15 s.

15. The method according to claim 14, characterized in that it consists of selecting the duration and/or the frequency and/or the intensity of the associated sounds (SA).
